(19) United States
(12) Patent Application Publication
(10) Pub. No.: US 2004/0061170 A1
(43) Pub. Date: Apr. 1, 2004

(54) Reverse blocking IGBT

(75) Inventor: Nathan Zommer, Los Altos, CA (US)

Correspondence Address: Townsend and Townsend and Crew LLP, 8th Floor, Two Embarcadero Center, San Francisco, CA, 94111, US

(73) Assignee: IXYS Corporation, Santa Clara, CA

(21) Appl. No.: 10/358,984

(22) Filed: Feb. 4, 2003

Related U.S. Application Data
(63) Continuation-in-part of application No. 09/617,214, filed on Jul. 17, 2000.
Application No. 09/617,214 is a continuation of application No. 08/870,507, filed on Jun. 6, 1997, now Pat. No. 6,091,086.
Application No. 08/870,507 is a division of application No. 08/508,753, filed on Jul. 31, 1995, now Pat. No. 5,698,454.

(51) Int. Cl. H01L 21/336; H01L 29/94

(52) U.S. Cl. 257/327; 257/328; 438/212; 438/268

(57) ABSTRACT

A method for forming a high voltage insulated gate bipolar transistor (“IGBT”) includes providing a semiconductor substrate of first conductivity type. The semiconductor substrate includes a front-side surface, a backside surface, and a scribe region. The substrate further includes a plurality of active cells on the front-side surface. A drain region of second conductivity type is formed using a first impurity proximate the backside surface of the substrate. A continuous conductive region of second conductivity type is formed using a second impurity that has been provided into the substrate from the backside surface of the substrate. The continuous conductive region extends from the front-side surface to the backside surface. The second impurity has a higher mobility than the first impurity.

### CROSS-REFERENCES TO RELATED APPLICATIONS

The present application is a continuation-in-part application of U.S. patent application Ser. No. 09/617,214, filed on Jul. 17, 2000, which is a continuation of U.S. patent application Ser. No. 08/870,507, filed on Jun. 6, 1997, now U.S. Pat. No. 6,091,086, which is a divisional of U.S. patent application Ser. No. 08/508,753, filed on Jul. 31, 1995, now U.S. Pat. No. 5,698,454, which are all incorporated by reference.

### BACKGROUND OF THE INVENTION

The present invention relates to integrated circuit devices, and in particular high voltage semiconductor switching devices such as high voltage transistors, power MOSFETs, IGBTs, thyristors, MCTs, and the like (hereinafter called power devices). Merely by way of example, the present invention is illustrated with an insulated gate bipolar transistor (IGBT) fabrication method and structure.

High voltage transistors such as conventional insulated gate bipolar transistors and the like, hereinafter referred to as conventional IBGTs, are fabricated by conventional semiconductor processing techniques on a single crystalline semiconductor substrate such as a silicon wafer. Conventional semiconductor processing techniques include doping and implanting, lithography, diffusion, chemical vapor deposition (CVD), wet and dry etching, sputtering, epitaxy, and oxidizing. A complex sequence of these processing techniques is often required to produce the conventional IGBT having a high breakdown voltage.

FIG. 1 illustrates a circuit diagram for the conventional IGBT 10. The conventional IGBT includes a gate terminal (G) 11, a drain terminal (D) 13, and a source terminal (S) 15. As shown, a positive voltage potential exists between the drain terminal 13 and the source terminal 15. No switching voltage exists at the gate terminal when the device is in an off-state, and no electrical current passes from the drain terminal 13 to the source terminal 15 in the off-state. The conventional IGBT turns “on” to an on-state when a switching voltage is applied to the gate terminal 11. Current passes from the drain terminal 13 to the source terminal 15 in the on-state.

The conventional IGBT includes a voltage blocking rating only in one direction. In particular, the conventional IGBT provides a “forward blocking” mode to block electrical current therethrough. In the forward blocking mode, the gate is in an off-state, high voltage appears on the drain terminal 13, and low voltage appears on the source terminal 15. Substantially no electrical current flows through the conventional IGBT in the forward blocking mode. It should be noted the forward blocking mode corresponds to the same biasing conditions on the drain terminal and the source terminal as the forward conduction mode, when the device is turned-on.

A limitation with the conventional IGBT 20 is device break down often occurs when relatively low voltage is applied to the device in a reverse blocking mode configuration as illustrated by FIG. 2. In the reverse blocking mode, a positive voltage potential is applied to the source terminal relative to the drain terminal, and the gate terminal is in an off-state. The relatively low voltage such as 30-50 volts applied to the source terminal 15, relative to the drain terminal 13, causes uncontrolled conduction of electrical current through the device even though the gate is in the off-state as illustrated by FIG. 3.

FIG. 3 illustrates I_{DS} (current drain to source) as a function of V_{DS} (voltage drain to source) for a conventional IGBT device having a breakdown voltage at about 1,800 volts. The conventional IGBT device breaks down causing an uncontrolled conduction of current through the device at about 1,800 volts in the forward blocking mode. At about −35 volts in the reverse blocking mode, uncontrolled conduction of electrical current occurs through the conventional IGBT device. The uncontrolled conduction of electrical current limits the application of the conventional IGBT to direct current configurations operating in the forward conduction mode.

It is often desirable to use an IGBT for alternating current (AC) applications. Conventional AC applications require the conventional IGBT to be subject to both positive and negative voltage potentials at source and drain terminals. However, the conventional IGBT simply cannot effectively block the negative voltage potential because of its limited reverse blocking rating. Accordingly, the conventional IGBT is limited to DC switch applications.

From the above, it is seen that a method and structure for providing a semiconductor device with a high breakdown voltage in both the forward and reverse conduction mode that is easy to manufacture, reliable, and cost effective is often desired.

### BRIEF SUMMARY OF THE INVENTION

According to the present invention, a high voltage IGBT integrated circuit device with high ratings for both forward and reverse biasing modes is provided. The present high voltage IGBT is often easy to fabricate includes a series of diffusions which are often easy to fabricate by way of conventional semiconductor fabrication techniques.

In a specific embodiment, the present invention provides a fabrication method for an integrated circuit, including a semiconductor layer of a first conductivity type. The semiconductor layer includes a front-side surface, a backside surface, and a scribe region. The semiconductor layer also includes a plurality of active cells on the front-side surface. The present method includes forming a backside layer of second conductivity type overlying the backside surface. The present method further includes forming a continuous diffusion region of the second conductivity type through the semiconductor layer to connect the scribe region to the backside layer.

In an alternative specific embodiment, the present invention provides a power integrated circuit device. The present power integrated circuit device includes a semiconductor layer of first conductivity type, where the semiconductor layer includes a front-side surface, a backside surface, and a scribe region. The semiconductor layer further includes a plurality of active cells on the front-side surface, and a backside layer of second conductivity type overlying the backside surface. A continuous diffusion region of the second conductivity type through the semiconductor layer to connect the scribe region to the backside layer is also included.

A further alternative embodiment includes a high voltage bipolar transistor switch. The present high voltage switch includes a high voltage alternating current power source including a first high voltage node and a second high voltage node. The present high voltage switch also includes a first bipolar transistor having a first source terminal, a first drain terminal, and a first gate terminal, and a second bipolar transistor having a second source terminal, a second drain terminal, and a second gate terminal. The second source is coupled to the first drain terminal at a first node, and the second drain terminal is coupled to the first source terminal at a second node. The second node is coupled to the second high voltage node. A load including a first load node and a second load node is also included. The first load node is coupled to the first node, and the second load node is coupled to the first high voltage node. Each of the first and second bipolar transistors further includes a semiconductor layer of first conductivity type, where semiconductor layer has a front-side surface, a backside surface, and a scribe region. The semiconductor layer further includes a plurality of active cells on the front-side surface. Each first and second bipolar transistor also includes a backside layer of second conductivity type overlying the backside surface. A continuous diffusion region of the second conductivity type through the semiconductor layer to connect the scribe region to the backside layer is also included.

In one embodiment, a method for forming a high voltage insulated gate bipolar transistor (“IGBT”) includes providing a semiconductor substrate of first conductivity type. The semiconductor substrate includes a front-side surface, a backside surface, and a scribe region. The substrate further includes a plurality of active cells on the front-side surface. A drain region of second conductivity type is formed using a first impurity proximate the backside surface of the substrate. A continuous conductive region of second conductivity type is formed using a second impurity that has been provided into the substrate from the backside surface of the substrate. The continuous conductive region extends from the front-side surface to the backside surface. The second impurity has a higher mobility than the first impurity.

In another embodiment, a method for forming a high voltage integrated circuit device includes providing a semiconductor substrate of first conductivity type, the semiconductor substrate including a upper surface and a lower surface, the substrate further including a plurality of active cells on the upper surface; forming a lower conductive region of second conductivity type using a first impurity proximate the lower surface of the substrate; and forming a vertical conductive region of second conductivity type using a second impurity that has been provided into the substrate from the lower surface of the substrate, the vertical conductive region extending substantially from the upper surface to the lower surface, the second impurity having a higher mobility than the first impurity, wherein a forward blocking rating of the device is different from a reverse blocking rating of the device.

In yet another embodiment, a method for forming a high voltage insulated gate bipolar transistor (“IGBT”) includes providing a semiconductor substrate of first conductivity type, the semiconductor substrate including a upper surface, a lower surface and a scribe region, the substrate further including a source region and a gate region proximate the upper surface; forming a drain region of second conductivity type using at least boron, the drain region being provided proximate the lower surface of the substrate; and forming a vertical conductive region of second conductivity type using at least aluminum that has been provided into the substrate from the lower surface of the substrate, the vertical conductive region corresponding to the scribe region and extending substantially from the upper surface to the lower surface, wherein the IGBT has a forward blocking rating of at least about 300 volts and a reverse blocking rating of at least about 100 volts.

A further understanding of the nature and advantages of the present invention may be realized by reference to the latter portions of the specification and attached drawings.

### BRIEF DESCRIPTION OF THE DRAWINGS

FIGS. 1-2 are circuit diagrams of a conventional IGBT device;

FIG. 3 is an illustration of breakdown voltage for a conventional IGBT device;

FIG. 4 is a simplified cross-sectional view of a conventional IGBT device;

FIG. 5 is a simplified cross-sectional view of an IGBT device according to the present invention;

FIG. 6 is a simplified illustration of breakdown voltage for the IGBT device of FIG. 5 according to the present invention;

FIG. 7 is a simplified circuit diagram of an IGBT according to the present invention; and

FIGS. 8-11 are fabrication methods of an IGBT according to the present invention.

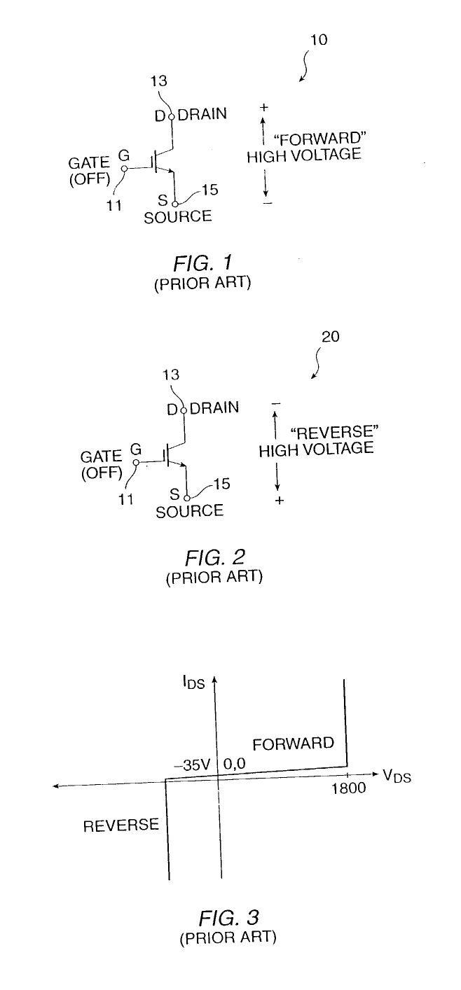

### DETAILED DESCRIPTION OF THE INVENTION

Conventional IGBT Structures

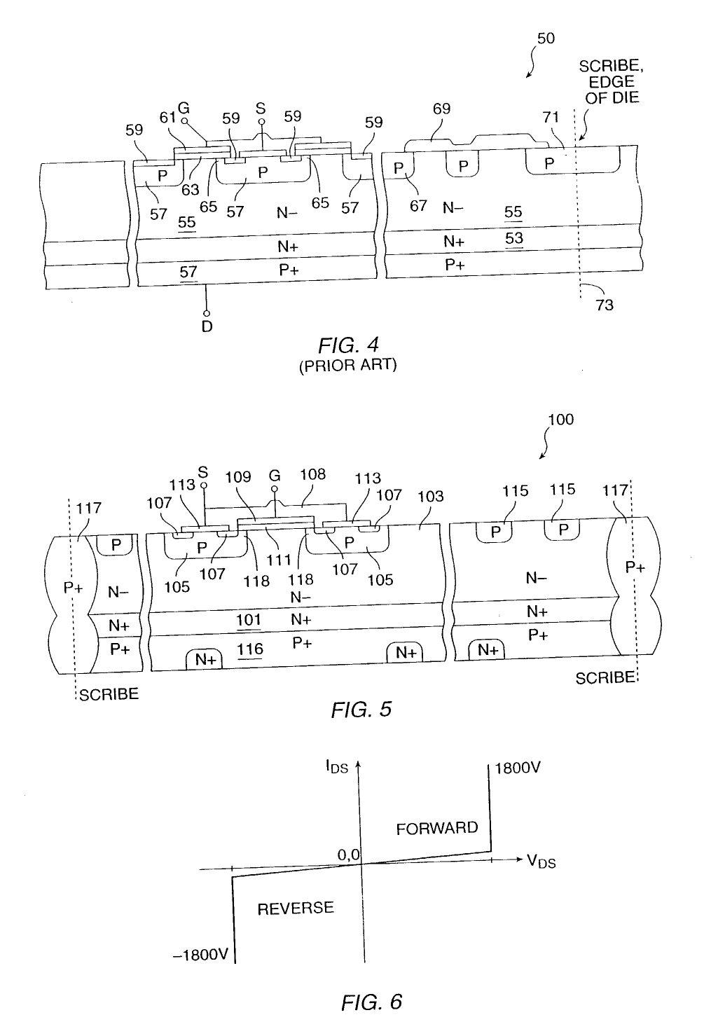

FIG. 4 is a simplified cross-sectional view 50 of a conventional IGBT integrated circuit device. The conventional IGBT device is often fabricated by a double diffused MOS process (DMOS). The conventional IGBT device 50 includes an N+ type substrate 53, an overlying N− type layer 55, and an underlying P+ type layer 57. P/P+ type well regions 57 are defined in the N− type layer 55. Each P/P+ type well region 57 includes an N type source 59 region defined within its perimeter. A gate polysilicon layer 61 is defined overlying a gate oxide layer 63 overlying a portion of the P/P+ type well region 57. A channel region 65 is defined in a portion of the P type well region between the N type source and a portion of the N− type layer. A gate (G), a source (S), and a drain (D) define the conventional IGBT device structure.

The conventional IGBT device also includes a plurality of P type guard ring regions 67 defined in the N− type layer 55. A field plate 69 typically made of polysilicon is defined overlying the guard ring regions 67. The conventional IGBT device further includes a P type scribe region 71 also defined in the N− type layer 55. The scribe region defines an outer edge of the integrated circuit chip after being removed from the wafer.

The conventional IGBT device of FIG. 4 forms an active region of a typical chip. An active area may comprise hundreds, thousands, or even millions of these microscopically small regions, each defining an active IGBT device. These devices may comprise cells which are all connected in parallel. Alternatively, these regions may comprise stripes or the like defining the active device. These structures of the active device, whether cells or strips, do not typically affect its high voltage characteristics.

Depending upon whether the conventional IGBT device shown in FIG. 4 operates as an IGBT (or thyristor) depends upon the resistance levels of the layers. For thyristor operation, latch-up is promoted by decreasing the doping in the P/P+ well regions while heavily doping the substrate. This also increases the gain through the device. Conventional IGBT operation, however, requires low resistivity through the N− type layer which does not promote latch-up. Thus, the dopant levels within each layer must be adjusted accordingly to provide IGBT (or thyristor) operation.

The conventional IGBT device provides for off-state voltage blocking to occur predominately in one direction. The conventional IGBT device includes a high forward blocking rating, but a low reverse blocking rating, thereby being limited to DC applications. The low reverse blocking rating occurs by way of the N+/P+ junction 73 which is exposed upon die separation. The exposed N+/P+ junction includes certain doping characteristics which cannot provide for a high breakdown voltage in the reverse conductive mode. For example, high voltage applied to the source terminal relative to the drain terminal creates a main P/P+ type well that is forward biased relative to the N− type layer, creating a diode P/N. The diode P/N is electrically in series with the N+/P+ junction, typically acting like a leaky “zener diode” by way of the unpassivated N+/P+ junction surfaces. The forward biased diode P/N in series with the unpassivated N+/P+ junction cause a low breakdown voltage through the device when the source terminal is high relative to the drain terminal, thereby creating a low reverse blocking rating. The low reverse blocking rating is often incompatible for use with AC applications and the like.

Present IGBT Structures

FIG. 5 is a simplified cross-sectional view of an IGBT integrated circuit device 100 according to the present invention. The present IGBT device may be formed by a double diffused MOS process (DMOS) and the like. Other fabrication techniques may also be used depending upon the particular application. The present IGBT device 100 includes an N+ type semiconductor substrate 101. In one embodiment, an N− type layer 103 is formed overlying the N+ type semiconductor substrate 101. The N− type layer 103 is often an epitaxial layer or the like. P/P+ type well regions 105 are defined onto the N− type layer 103. In another embodiment, the IGBT device 100 is formed without the N− type or epitaxial layer 103.

The present IGBT device also includes a plurality of N type source regions 107 defined into a perimeter of each P/P+ type well region 105. The present IGBT device includes a gate polysilicon layer (G) 109 defined overlying a thin layer of gate oxide 111 and the like. Source metallization 113 is defined overlying the N type source regions 107, and connects 108 each source region together. A P type diffusion region 116 is defined overlying the backside of the N+ type substrate. The P type diffusion region is a P+ type drain region. A channel region 118 is defined in a portion of the P/P+ type well region between the source region 107 and a portion of the N− type layer 103.

The present IGBT device also includes a plurality of guard ring structures 115. The guard ring structures are each P type diffusions, typically surrounding the periphery of the integrated circuit chip active cell region. A field plate (not shown) made of polysilicon is often defined overlying the guard ring structures. The guard ring structure tends to keep the main conduction region toward the active cell region of the integrated circuit chip, thereby preserving the voltage rating of the device.

A P type region 117 defines the scribe line of the present IGBT device. The P type region 117 is also referred to as a continuous diffusion region or vertical conductive region. The P type region creates a “wrap around” P type envelope covering sides of the die including the bottom P+ type drain region. The P type region eliminates the exposed P+/N+ junction of the convention IGBT device of FIG. 4. Thus, the present IGBT device promotes breakdown to occur at the P+/N junction interface, thereby preserving the high breakdown voltage of the device in both reverse and forward blocking modes.

In one embodiment, the device 100 is provided with a reverse blocking rating of 100 volts, 150 volts, 200 volts, 250 volts, 300 volts, 500, volts, or greater, and a forward blocking rating of 300 volts, 400 volts, 500 volts, 600 volts, 800 volts, 1,000 volts or greater. The forward blocking rating and the reverse blocking rating may or may not be substantially the same. That is, in one implementation, the forward and reverse blocking ratings (or breakdown voltages) are the different. For example, the device 100 has the reverse blocking rating of about 100-300 volts and the forward blocking rating of greater than 300 volts. Generally, it has been discovered that it is cost effective to provide the device 100 with the reverse blocking rating of about 100 volts or more and the forward blocking of about 600 volts or more. In another implementation, the forward blocking rating and the reverse blocking rating are substantially the same, e.g., about 500-600 volts, respectively.

In one embodiment, the reverse blocking rating of the device 100 corresponds to the number of guard ring structures 115 provided on the substrate. Accordingly, the reverse blocking rating may be increased or decreased by increasing or decreasing the number of the guard rings provided on the substrate according to the present embodiment.

FIG. 6 is a simplified illustration of breakdown voltage of the IGBT device of FIG. 4 according to the present invention. The present IGBT shows current IDS (current drain to source) as a function of voltage VDS (voltage drain to source) for a 1,800 volt device. The present IGBT device passes substantially no electrical current through the device until the voltage between the source and drain reaches the breakdown voltage of about 1,800 volts and greater or −1,800 volts and less. At the breakdown voltage, the present IGBT device passes electrical current via breakdown. Substantially no electrical current passes through the present IGBT device until breakdown occurs or the proper switching voltage is applied to the gate terminal of the device. Accordingly, the present IGBT device includes a high forward blocking rating and a high reverse blocking rating.

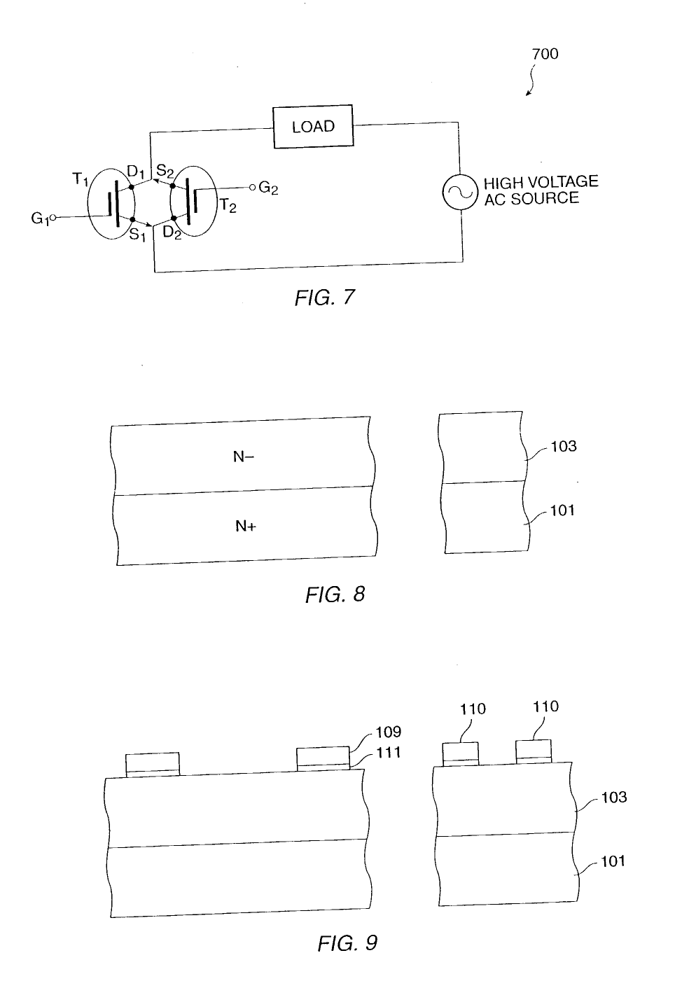

FIG. 7 is a simplified circuit diagram 700 of an AC switch according to the present invention. The circuit diagram 700 includes IGBT T1 and IGBT T2. Each IGBT includes a source terminal S1, S2, a gate terminal G1, G2, and a drain terminal D1, D2. The source terminal S1 connects to the drain terminal D2 at a first node, and the source terminal S2 connects to the drain terminal D1 at a second node. The first node connects to an AC power source, and the second node connects to a load. The AC power source also connects to the load to complete the switch loop. AC power is applied to the load by way of selectively providing switching voltages to the transistor gates G1 and G2.

Switching voltages at the gate terminals turn on each of the IGBT transistors at selected times to allow AC current to pass therethrough. For example, voltage applied to gate G2 passes positive current via positive alternation through transistor T2, and voltage applied to gate G1 passes negative current via negative alternation through transistor T1. By way of the present IGBT structure, each of the IGBT transistors may block voltage in forward and reverse blocking modes for application with the AC power source. The breakdown voltage of each transistor is, for example, 1,800 volts and greater. The breakdown voltage of each transistor may also be 300 volts and greater, 600 volts and greater, or 3,000 volts and greater. The AC power source can provide an AC voltage at about 300 volts and greater, or at about 600 volts and greater, or at about 1,800 volts and greater, or at about 3,000 volts and greater. Of course, the breakdown voltage of each IGBT device and the voltage produced by the AC power supply depend upon the particular application.

FIGS. 8-11 illustrate a simplified method of fabrication for the present high voltage IGBT device. The present fabrication method begins with a semiconductor substrate such as an N+ type substrate 101 and the like of FIG. 8. It should be noted that the present fabrication method relies upon an N+ type substrate, but may also use other types of substrates. The N+ type substrate includes an N− type layer 103 defined thereon by way of standard chemical vapor deposition (CVD) techniques and the like. The N− type layer includes an N type impurity such as phosphorous or the like at a concentration ranging from about 10¹³ atoms/cm³ to about 10¹⁷ atoms/cm³, and is preferably at about 4×10¹³ atoms/cm³ for preferred bipolar transistor operation. Relative to the N− type layer, the N+ type semiconductor substrate includes an N type impurity such as phosphorous or the like at a concentration ranging from about 10¹⁵ atoms/cm³ to about 10¹⁹ atoms/cm³, and is preferably at about 10¹⁷ atoms/cm³. Of course, other concentrations may also be provided depending upon the particular application.

Active IGBT devices define onto the N− type layer by way of, for example, a double diffused MOS (DMOS) technique and others. The DMOS technique defines a gate electrode layer 109 overlying a thin layer of high quality oxide 111 as illustrated by FIG. 9. The gate electrode layer is typical made of polysilicon and the like, which is preferably doped with an N type dopant material for conductivity. Steps of masking and etching define the gate electrodes (G) overlying the thin high quality oxide formed over the N− type layer. Also shown are field plate layers formed overlying a portion of the N− type layer.

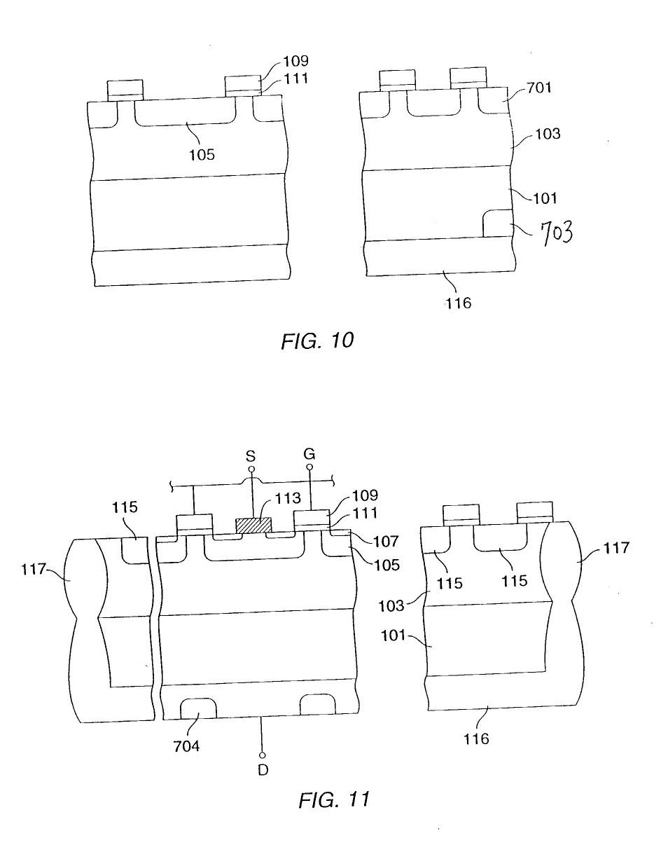

An implant step(s) forms P type well regions 105 in the N− type layer as illustrated by FIG. 10. Each P type well region is preferably a P/P+ type well or the like, and is defined between each of the gate electrodes. The P type well region includes a boron impurity concentration ranging from about 10¹⁴ atoms/cm³ to about 10¹⁸ atoms/cm³, and is preferably at about 10¹⁶ atoms/cm³. The implant step also forms P type guard ring region(s) 115. The P type guard ring regions are defined at an outer periphery of the active cell region for the purpose of preventing the conductive region of forming outside the main junction region. Thus, the P type guard ring regions preserve the high voltage characteristics of the present IGBT device.

A P type region 116 defining a drain region (D) is formed overlying the backside of the N+ type semiconductor substrate in an implant step. The P type region includes a boron impurity concentration ranging from about 10¹⁵ atoms/cm³ to about 10¹⁸ atoms/cm³, and is preferably at about 10¹⁸ atoms/cm³. A subsequent diffusion step creates the P type drain region which can range in depth from about 50 microns to about 300 microns, and is preferably at about 100 microns for a 600 volt to 3,000 volt IGBT device. The P type impurity for the P type well region, the P type guard ring region, and the P type drain region is preferably boron or the like.

A P type region 701 is also defined at the scribe line of the integrated circuit chip. A P type region 703 is also defined from the backside of the wafer. Both of the P type regions are defined by way of sputtering, implantation or the like using an impurity with a higher mobility than, for example, the P type well region, the P type guard ring region, and the P type drain region. By way of a subsequent diffusion step(s), the P type regions 701, 703 diffuse faster than the P type impurities of, for example, the well region, the guard ring region, and the drain region. The faster diffusion rate allows the P type regions 701 and 703 to connect to each other to form the region 117.

The diffusion of aluminum vertically into the substrate forms a continuous P type “frame” (or diffusion region) around the periphery of the integrated circuit, thereby eliminating the N+/P+ junction region of the conventional IGBT device. The P type impurity with the higher mobility is preferably aluminum or the like. A step of selective sputtering coats selected regions of the integrated circuit with the aluminum for subsequent thermal diffusion or the like.

In one embodiment, the boron impurity in the P type region 116 and the aluminum impurity in the P type regions 701 and 703 are diffused in to the substrate to form the drain region and the vertical conductive region 117 in the same diffusion process in the same furnace. Accordingly, using two impurity types having different mobility rates simplifies the fabrication process. Alternatively, more than one diffusion steps and/or furnaces may be used.

In one embodiment, the vertical conductive region 117 formed using only aluminum from the P type region 703. That is, the P type region 701 is not formed to reduce contamination issues on the front side of the substrate since a plurality of active cells are formed thereon. Therefore, aluminum is sputtered or deposited only on the backside of the substrate (to form the P type region 703) and thereafter diffused into the substrate from the backside to form the continuous diffusion region 117. As used herein, the terms “sputter” and “deposit” are used interchangeably.

A source implant step forms an N type source region(s) 107 (S) within the periphery of the P type well region(s) 105. The source implant is preferably an arsenic implant where the arsenic is at a concentration ranging from about 10¹⁷ atoms/cm³ to about 10²⁰ atoms/cm³, and is preferably at about 3×10¹⁹ atoms/cm³. A metallization layer typically aluminum or the like defines a source metallization layer. As shown, the source (S), the gate (G), and the drain (D) define the IGBT according to the present invention.

Optionally, an N+ type dopant 704 such as phosphorous or the like forms selected N+ type regions in the drain region. The N+ type regions modify the present IGBT device performance for special switching and forward voltage drop characteristics. The N+ type regions includes a phosphorous impurity at a concentration ranging from about 10¹⁶ atoms/cm³ to about 10¹⁹ atoms/cm³, and is preferably at about 7×10¹⁸ atoms/cm³.

While the above is a full description of the specific embodiments, various modifications, alternative constructions, and equivalents may be used. For example, while the description above is in terms of P type well region, it would be possible to implement the present invention with an N type well region, or the like. Furthermore, while the embodiments shown are generally in terms of an MOSFET, thyristor, and IGBT, it would be possible to implement the improved substrate in the present invention with any device such as, for example, an MCT, or the like.

Therefore, the above description and illustrations should not be taken as limiting the scope of the present invention which is defined by the appended claims.

What is claimed is:

1. A method for forming a high voltage insulated gate bipolar transistor (“IGBT”), said method comprising:
providing a semiconductor substrate of first conductivity type, the semiconductor substrate including a front-side surface, a backside surface, and a scribe region, the substrate further including a plurality of active cells on the front-side surface;
forming a drain region of second conductivity type using a first impurity proximate the backside surface of the substrate; and
forming a continuous conductive region of second conductivity type using a second impurity that has been provided into the substrate from the backside surface of the substrate, the continuous conductive region extending from the front-side surface to the backside surface, the second impurity having a higher mobility than the first impurity.

2. The method of claim 1, wherein the IGBT has a forward breakdown voltage of a first value and a reverse breakdown of a second value that is different from the first value.

3. The method of clam 1, wherein the IGBT has a forward blocking rating of about 300 volts or more and a reverse blocking rating of about 100 volts or more.

4. The method of claim 1, wherein the plurality of active cells includes a source region and a gate region.

5. The method of claim 1, wherein the continuous conductive region is formed by diffusing the second impurity from the backside of the substrate.

6. The method of claim 5, wherein the first impurity is boron and the second impurity is aluminum.

7. The method of claim 6, further comprising:
providing a first concentration of aluminum at a first location on the backside of the substrate, the first location corresponding to a lower portion of the continuous conductive region, wherein the first concentration of aluminum is diffused upward into the substrate to form the continuous conductive region.

8. The method of claim 7, further comprising:
providing a second concentration of aluminum at a second location on the front-side of the substrate, the second location corresponding to an upper portion of the continuous conductive region, wherein the second concentration of aluminum is diffused downward into the substrate to form the continuous conductive region.

9. The method of claim 7, further comprising:
providing a backside conductive region of second conductive type proximate the backside of the substrate using boron, wherein the boron from the backside conductive region and the aluminum from the first concentration are diffused upward together to form the drain region and the continuous conductive region.

10. A method for forming a high voltage integrated circuit device, the method comprising:
providing a semiconductor substrate of first conductivity type, the semiconductor substrate including a upper surface and a lower surface, the substrate further including a plurality of active cells on the upper surface;
forming a lower conductive region of second conductivity type using a first impurity proximate the lower surface of the substrate; and
forming a vertical conductive region of second conductivity type using a second impurity that has been provided into the substrate from the lower surface of the substrate, the vertical conductive region extending substantially from the upper surface to the lower surface, the second impurity having a higher mobility than the first impurity,
wherein a forward blocking rating of the device is different from a reverse blocking rating of the device.

11. The method of claim 10, wherein the forward blocking rating is about 600 volts or more and the reverse blocking rating is about 100 volts or more.

12. The method of claim 10, wherein the forward blocking rating is about 600 volts or more and the reverse blocking rating is about 200 volts or more.

13. The method of claim 10, wherein the high voltage integrated circuit device is an insulated gate bipolar transistor.

14. The method of claim 13, wherein the lower conductive region defines a drain region and includes a plurality of well regions of first conductivity type.

15. The method of claim 10, wherein the first impurity is boron and the second impurity is aluminum.

16. The method of claim 15, wherein the forming-a-vertical-conductive-region step includes:
sputtering aluminum onto a first location at the lower surface of the substrate, the first location corresponding to a lower portion of a scribe region of the substrate; and
diffusing the sputtered aluminum upward into the substrate from the first location.

17. A method for forming a high voltage insulated gate bipolar transistor (“IGBT”), the method comprising:
providing a semiconductor substrate of first conductivity type, the semiconductor substrate including a upper surface, a lower surface and a scribe region, the substrate further including a source region and a gate region proximate the upper surface;
forming a drain region of second conductivity type using at least boron, the drain region being provided proximate the lower surface of the substrate; and
forming a vertical conductive region of second conductivity type using at least aluminum that has been provided into the substrate from the lower surface of the substrate, the vertical conductive region corresponding to the scribe region and extending substantially from the upper surface to the lower surface,
wherein the IGBT has a forward blocking rating of at least about 600 volts and a reverse blocking rating of at least about 100 volts.

18. The method of claim 17, further comprising:
providing a first concentration of aluminum at a first location on the lower surface of the substrate, the first location corresponding to a lower portion of the scribe region; and
providing a lower conductive region of second conductive type proximate the lower surface of the substrate using at least boron,
wherein the boron from the lower conductive region and the aluminum from the first concentration are diffused upward together to form the drain region and the vertical conductive region.

19. The method of claim 18, wherein the IGBT has the reverse blocking rating of at least about 200 volts.

20. The method of claim 17, wherein the forward blocking rating is different from the reverse blocking rating.
